(19) United States
(12) Patent Application Publication
(10) Pub. No.: US 2008/0308813 A1
(43) Pub. Date: Dec. 18, 2008

(54) HIGH BREAKDOWN ENHANCEMENT MODE GALLIUM NITRIDE BASED HIGH ELECTRON MOBILITY TRANSISTORS WITH INTEGRATED SLANT FIELD PLATE

(76) Inventors: Chang Soo Suh, Goleta, CA (US); Yuvaraj Dora, Vellore (IN); Umesh K. Mishra, Montecito, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/841,476

(22) Filed: Aug. 20, 2007

Related U.S. Application Data
(60) Provisional application No. 60/822,886, filed on Aug. 18, 2006.

(51) Int. Cl. H01L 29/778; H01L 21/338

(52) U.S. Cl. 257/76; 257/194; 438/172; 257/E21.403; 257/E29.246

(57) ABSTRACT

High breakdown enhancement mode gallium nitride (GaN) based high electron mobility transistors (HEMTs) with integrated slant field plates. These HEMTs have an epilayer structure comprised of AlGaN/GaN buffer. Before the formation of the gate electrode, a passivation layer is deposited, and then the opening for the gate is patterned. The passivation layer below the gate is etched using an etch condition that creates a slanted sidewalls. Then, the charge below the channel is removed either by Fluorine-based plasma treatment and/or by a recess etch. The gate metal is deposited with an angled rotation to form a gate structure with an inherent field plate with rounded edges.

### CROSS-REFERENCE TO RELATED APPLICATION

This application claims the benefit under 35 U.S.C. Section 119(e) of the following co-pending and commonly-assigned U.S. patent application:

U.S. Provisional Application Ser. No. 60/822,886, filed on Aug. 18, 2006, by Chang Soo Suh, Yuvaraj Dora and Umesh Mishra, entitled “HIGH BREAKDOWN ENHANCEMENT MODE GaN-BASED HEMTS WITH INTEGRATED SLANT FIELD PLATE,” attorneys' docket number 30794.193-US-P1 (2006-730-1);

which application is incorporated by reference herein.

This application is related to the following co-pending and commonly-assigned U.S. patent applications:

U.S. Utility Application Ser. No. 10/581,940, filed on Mar. 8, 2006, by Alessandro Chini, Umesh K. Mishra, Primit Parikh and Yifeng Wu, entitled “FABRICATION OF SINGLE OR MULTIPLE GATE FIELD PLATES”, attorney's docket number 30794.105-US-WO (2004-091), which application claims the benefit under 35 U.S.C Section 365(c) of PCT Application Ser. No. US2004/02932, filed on Sep. 9, 2004, by Alessandro Chini, Umesh K. Mishra, Primit Parikh and Yifeng Wu, entitled “FABRICATION OF SINGLE OR MULTIPLE GATE FIELD PLATES”, attorney's docket number 30794.105-WO-U1 (2004-091), which application claims the benefit under 35 U.S.C Section 119(e) of U.S. provisional Patent Application Ser. No. 60/501,557, filed on Sep. 9, 2003, by Alessandro Chini, Umesh K. Mishra, Primit Parikh and Yifeng Wu, entitled “FABRICATION OF SINGLE OR MULTIPLE GATE FIELD PLATES”, attorney's docket number 30794.105-US-P1 (2004-091);

U.S. Utility Application Ser. No. 11/523,268, filed on Sep. 18, 2006, by Siddharth Rajan, Chang Soo Suh, James S. Speck and Umesh K. Mishra, entitled “N-POLAR ALUMINUM GALLIUM NITRIDE/GALLIUM NITRIDE ENHANCEMENT-MODE FIELD EFFECT TRANSISTOR,” attorneys docket number 30794.148-US-U1, (2006-107); which application claims the benefit under 35 U.S.C Section 119(e) of U.S. Provisional Application Ser. No. 60/717,996, filed on Sep. 16, 2005, by Siddharth Rajan, Chang Soo Suh, James S. Speck and Umesh K. Mishra, entitled “N-POLAR ALUMINUM GALLIUM NITRIDE/GALLIUM NITRIDE ENHANCEMENT-MODE FIELD EFFECT TRANSISTOR,” attorneys docket number 30794.148-US-P1, (2006-107);

U.S. Utility Patent Application Ser. No. 11/599,874, filed Nov. 15, 2006, by Tomas Palacios, Likun Shen and Umesh K. Mishra, entitled “FLUORINE TREATMENT TO SHAPE THE ELECTRIC FIELD IN ELECTRON DEVICES, PASSIVATE DISLOCATIONS AND POINT DEFECTS, AND ENHANCE THE LUMINESCENCE EFFICIENCY OF OPTICAL DEVICES,” attorneys' docket number 30794.157-US-U1 (2006-129); which application claims the benefit under 35 U.S.C Section 119(e) of U.S. Provisional Application Ser. No. 60/736,628, filed on Nov. 15, 2005, by Tomas Palacios, Likun Shen and Umesh K. Mishra, entitled “FLUORINE TREATMENT TO SHAPE THE ELECTRIC FIELD IN ELECTRON DEVICES, PASSIVATE DISLOCATIONS AND POINT DEFECTS, AND ENHANCE THE LUMINESCENCE EFFICIENCY OF OPTICAL DEVICES,” attorneys' docket number 30794.157-US-P1 (2006-129);

U.S. Provisional Application Ser. No. 60/908,914, filed on Mar. 29, 2007, by Umesh K. Mishra, Yi Pei, Siddharth Rajan, and Man Hoi Wong, entitled “N-FACE HIGH ELECTRON MOBILITY TRANSISTORS WITH LOW BUFFER LEAKAGE AND LOW PARASITIC RESISTANCE,” attorney's docket number 30794.215-US-P1 (2007-269-1);

U.S. Provisional Application Ser. No. 60/941,580, filed on Jun. 1, 2007, by Chang Soo Suh and Umesh K. Mishra, entitled “P-GaN/AlGaN/AlN/GaN ENHANCEMENT-MODE FIELD EFFECT TRANSISTOR,” attorney's docket number 30794.229-US-P1 (2006-575); and

U.S. Provisional Application Ser. No. 60/939,542, filed on May 22, 2007, by Umesh K. Mishra, James S. Speck, Rongming Chu, and Felix Recht, entitled “METHOD OF FABRICATING III-NITRIDE DEVICES WITH REDUCED LEAKAGE CURRENT,” attorney's docket number 30794.240-US-P1 (2007-676);

which applications are incorporated by reference herein.

### STATEMENT REGARDING FEDERALLY SPONSORED RESEARCH AND DEVELOPMENT

This invention was made with Government support under Grant No. N0001401-1-0764 awarded by the Office of Naval Research. The Government has certain rights in this invention.

### BACKGROUND OF THE INVENTION

1. Field of the Invention

This invention relates to high breakdown enhancement mode (E-mode) gallium nitride (GaN) based high electron mobility transistors (HEMTs) with integrated slant field plates.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

A High Electron Mobility Transistor (HEMT) is a field effect transistor (FET) where the channel is a heterojunction between two materials with different bandgaps. For this reason, HEMTs are also known as heterostructure FETs (HFETs).

The heterojunction is a thin layer where the Fermi energy is above the conduction band, giving the channel low resistance or high electron mobility. This thin layer is also known as a two-dimensional electron gas (2DEG). A voltage applied to the gate alters the conductivity of this layer.

Aluminum gallium nitride (AlGaN)/gallium nitride (GaN) HEMTs have been attracting significant interest for power switching applications owing to the possibility of delivering high breakdown voltages (V_{BD}) and low on-resistances (R_{ON}) beyond the material limits of silicon (Si) and silicon carbide (SiC). Although much attention has been focused on depletion-mode (D-mode) AlGaN/GaN HEMTs, enhancement-mode (E-mode) AlGaN/GaN HEMTs are especially desirable for power switching applications due to the added safety of a normally-off device.

The present invention describes high breakdown E-mode AlGaN/GaN HEMTs with V_{BD} of 1400 V (at V_{GS}=0 V) and R_{ON} below 3 mΩ cm². E-mode operation is achieved via self-aligned Fluorine-based plasma treatment below the gate and the integration of self-aligned slant field plate technology yielded the highest V_{BD} value among reported E-mode GaN-based HEMTs.

### SUMMARY OF THE INVENTION

The present invention discloses a high breakdown E-mode GaN-based HEMT with an integrated slant field plate. The integrated slant field plate reduces a peak electric field under the HEMT's gate by spreading the electric field laterally from underneath the gate, wherein the integrated slant field plates is integrated with the gate by shaping the gate into a field plate. At least one portion of at least one of the gate's sidewalls may overhang the HEMT's channel by extending or slanting at one or more acute angles away from the channel, thereby shaping the gate into a field plate. The gate may be a gate structure with an inherent field plate and rounded edges.

The integrated slant field plate may split peak electric fields under the gate into at least two smaller peaks, on either side of the gate and underneath the sidewalls, and the rounded edges may broaden terminating points of electric fields in the HEMT, so that the HEMT exhibits higher breakdown voltages as compared to conventional devices without the integrated slant field plate.

The HEMT's channel may be a heterojunction formed between a first nitride material on a second nitride material, and the gate contacts the first nitride material. The first nitride material may be AlGaN and the second nitride material may be GaN, for example.

The HEMT may further comprise a passivation layer deposited on the first nitride layer, an opening in the passivation layer having passivation layer sidewalls slanting at one or more acute angles away from the channel, and gate metal deposited in the opening, on the passivation layer sidewalls, and on the first nitride material, to form the integrated slant field plate. The passivation layer below the gate may be etched using an etch condition that creates the slanted passivation layer sidewalls.

Charge below the gate may be removed by Fluorine-based plasma treatment of the first nitride material in a region where the gate contacts the first nitride material. Charge below the gate may be removed by a recess etched in the first nitride material in a region where the gate contacts the first nitride material.

The present invention also discloses a GaN based HEMT with an on resistance below 3 mΩ cm². The GaN based HEMT may have a gate breakdown voltage of at least 1400 V for a gate-source voltage of 0 V.

The present invention also discloses a method for fabricating a HEMT comprising depositing a passivation layer on a nitride barrier material of the HEMT, etching the passivation layer to form one or more slanted features of the passivation layer extending at one or more acute angles away from the channel and to expose some of the nitride barrier material beneath the passivation layer, depositing gate metal on the exposed nitride barrier material and on the slanted features to form an integrated slant field plate. The gate metal may be deposited with an angled rotation to form a gate structure with an inherent field plate with rounded edges.

The present invention also discloses a method for fabricating a gate of a HEMT, comprising integrating a slant field plate with a gate of the HEMT. The integrating may comprise shaping one or more sidewalls of the gate so that at least one portion of the sidewalls overhangs a channel by extending at one or more acute angles away from the channel. The HEMT has increased breakdown voltage and reduced on-resistance as compared to a gate which does not have a slant field plate.

### BRIEF DESCRIPTION OF THE DRAWINGS

Referring now to the drawings in which like reference numbers represent corresponding parts throughout:

FIG. 1(a) is a cross-section schematic of a Fluorine-based plasma-treated HEMT with integrated slant field plate, FIG. 1(b) is a cross-section schematic of a gate-recessed HEMT with integrated slant field plate, and FIG. 1(c) is a cross-section schematic of a gate-recessed Fluorine-based plasma-treated E-mode HEMT with integrated slant field plate.

FIGS. 2 and 2(a)-2(i) illustrate the fabrication process according to the preferred embodiment of the present invention.

FIG. 3 is a graph that illustrates the off-state DC-IV plot of the first demonstration of a Fluorine-based plasma-treated E-mode AlGaN/GaN HEMT with integrated slant field plate.

FIG. 4 is a graph that illustrates the DC, 80 μs, and 200 ns pulsed current-voltage output characteristics of the preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses a novel E-mode AlGaN/GaN HEMT structure with an integrated slant field plate. The HEMT has an epilayer structure as comprising AlGaN on a GaN buffer. Before the formation of the gate electrode, a passivation layer is deposited, and then the opening for the gate is patterned. The passivation layer below the gate is etched using an etch condition that creates slanted sidewalls. Then, the charge below the channel is removed either by Fluorine-based plasma treatment and/or by a recess etch. The gate metal is deposited with an angled rotation to form a gate structure with an inherent field plate with rounded edges. Since the field plate splits peak electric fields into two smaller peaks and the rounded edges broaden the terminating points of electric fields, this structure exhibits much higher breakdown voltages than conventional devices.

Technical Description

The present invention demonstrates low on-resistance and high breakdown voltage beyond the material limits of Si and SiC in fully passivated D-mode AlGaN/GaN HEMTs by integration of a self-aligned “slant” field plate [1]. These results further advocate GaN-based HEMTs as prominent candidate for the next generation of devices for power-electronics. Although much of the focus has been given to D-mode devices, E-mode devices continue to receive increasing attention as they provide the added safety of a normally-off operation. E-mode operation on AlGaN/GaN buffer structures is achieved by using a recess etch and/or Fluorine-based plasma treatment below the gate contact [2-4].

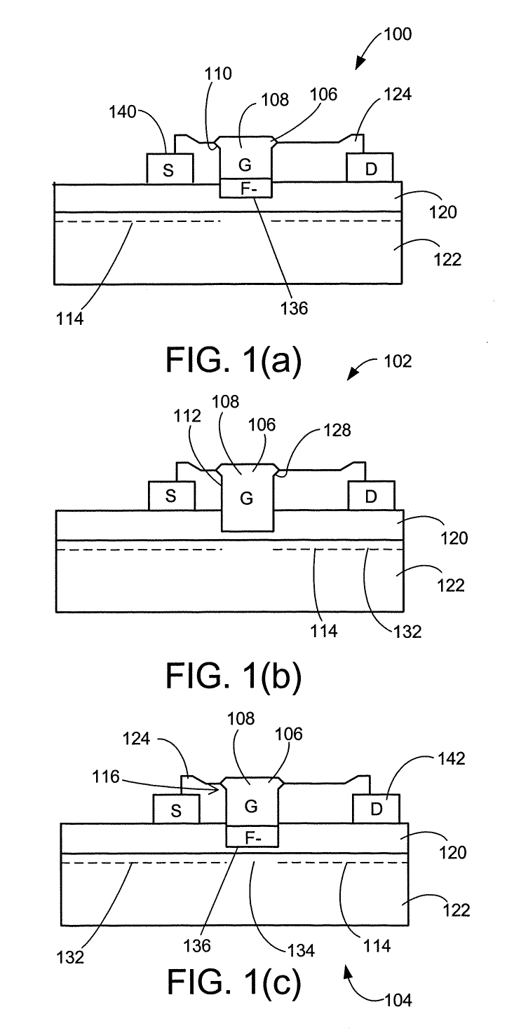

This invention also presents E-mode devices that take advantage of the integrated self-aligned slant field plate for realization of low on-resistance and high breakdown voltage in E-mode GaN-based HEMTs. The device structures are shown in FIGS. 1(a), (b) and (c). Fluorine-based plasma-treated 100, gate-recessed 102, and gate-recessed and Fluorine-based plasma-treated 104 E-mode HEMTs are shown in FIGS. 1(a), 1(b), and 1(c), respectively. Each of the E-mode GaN based HEMTs 100, 102 and 104 has an integrated slant field plate 106 that reduces a peak electric field under the HEMT's gate 108 by spreading the electric field laterally from underneath the gate 108, wherein the integrated slant field plate 106 is integrated with the gate (G) 108 by shaping the gate 108 into a field plate 106. At least one portion 110 of at least one of the gate's sidewalls 112 may overhang the HEMT's channel 114 by extending or slanting from the sidewall 112, beginning at 116, at an acute angle in a direction away from the channel 114, thereby shaping the gate 108 into a field plate. The gate 108 may be a gate structure with an inherent field plate 106 and rounded edges 118.

The integrated slant field plate 106 may split peak electric fields under the gate 108 into at least two smaller peaks, on either side of the gate 108 and underneath the sidewalls 112, and the rounded edges 118 may broaden terminating points of electric fields in the HEMT, so that the HEMT exhibits higher breakdown voltages as compared to conventional devices without the integrated slant field plate 106.

The HEMT's channel 114 may be a heterojunction formed between a first nitride material 120 on a second nitride material 122, and the gate 108 contacts the first nitride material 120. The first nitride material 120 may be AlGaN and the second nitride material 122 may be GaN, for example.

The HEMT may further include a passivation layer 124 deposited on the first nitride layer 120, an opening 126 in the passivation layer 124 having passivation layer sidewalls 128 slanting upward from the first nitride material 120, at 130, at an acute angle in a direction away from the channel 114, and gate metal 108 deposited in the opening 126, on the passivation layer sidewalls 128, and on the first nitride material 120, to form the integrated slant field plate 106. The passivation layer 124 below the gate 108 may be etched using an etch condition that creates the slanted passivation layer sidewalls 128.

Typically, there is charge 132 in the HEMT channel 114. However, charge 132 in the channel 114 and below the gate 108 may be removed, to form a charge depleted region 134, using Fluorine-based plasma treatment 136 of the first nitride material 120 in a region where the gate 108 contacts the first nitride material 120. Charge 132 below the gate 108 may be removed, to form a charge depleted region 134, by a recess 138 etched in the first nitride material 120 in a region where the gate 108 contacts the first nitride material 120.

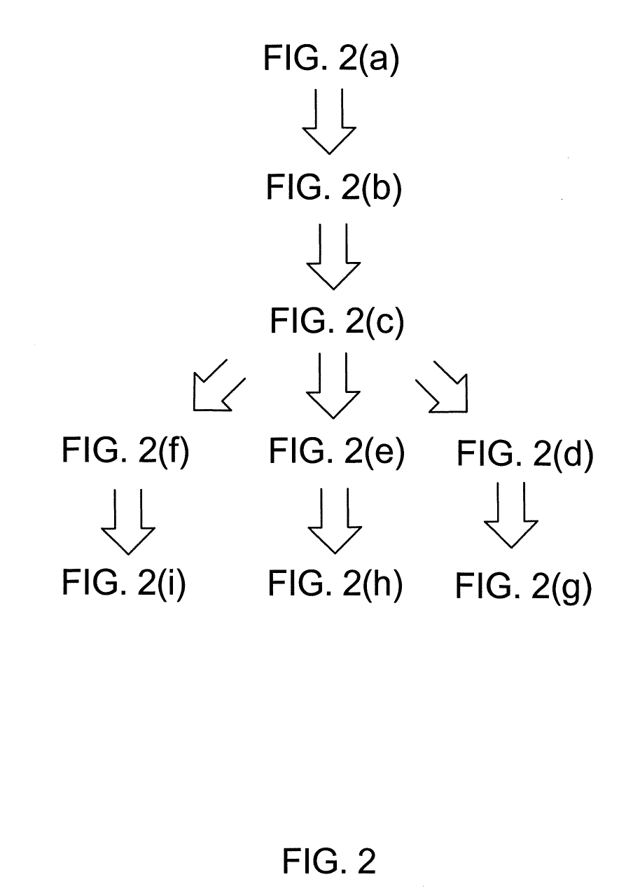

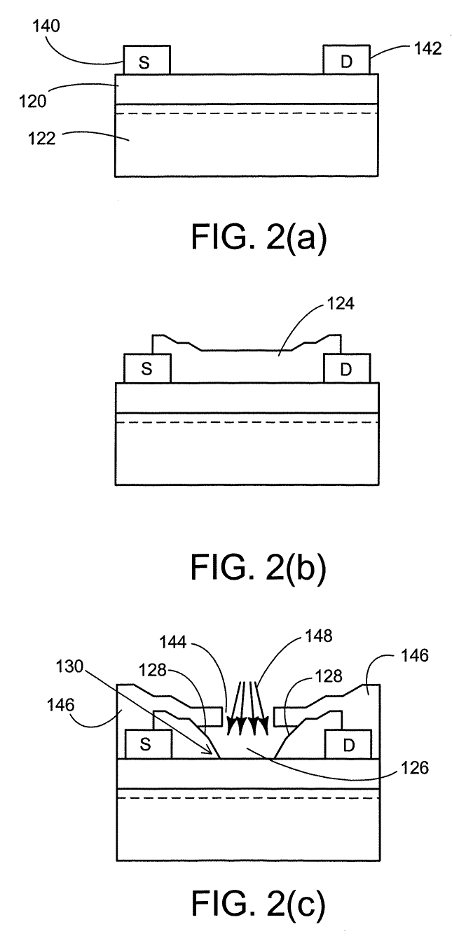

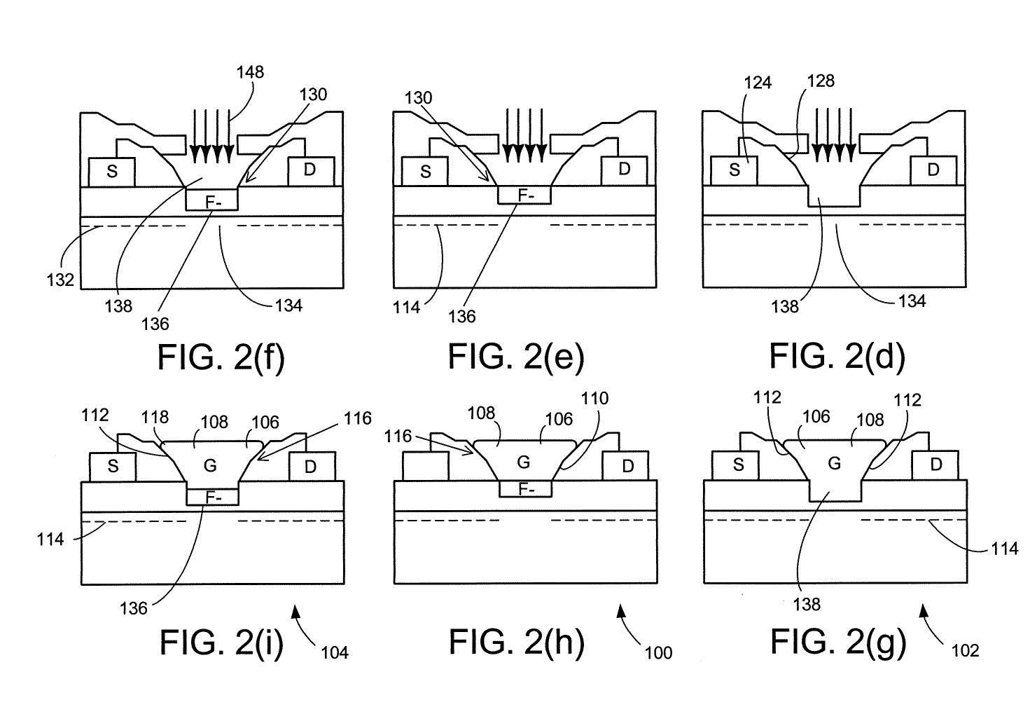

FIGS. 2 and 2(a)-2(i) illustrate the steps of a method for fabricating HEMT devices 100, 102 or 104, according to the preferred embodiment of the present invention. The sequence of steps in the method is illustrated in FIG. 2 and first comprises FIG. 2(a), FIG. 2(b), and FIG. 2(c), which are followed by either the sequence of steps comprising FIG. 2(d) and FIG. 2(g), the sequence of steps comprising FIG. 2(e) and FIG. 2(h), or the sequence of steps comprising FIG. 2(f) and FIG. 2(i). These various steps are described in more detail below.

First, as illustrated in FIG. 2(a), ohmic contacts, comprising source (S) 140 and drain (D) 142, are formed and isolated by a mesa etch. Next, as illustrated in FIG. 2(b), a passivation layer 124 is deposited on the AlGaN 120 to eliminate DC-RF dispersion. As shown in FIG. 2(c), a gate opening 144 is then patterned in a mask 146 on the passivation layer 124, so that the passivation layer 124 can be etched 148 under high pressure conditions (which leads to some lateral etching) to create at least one slanted feature 128 of the passivation layer 124, and to expose some of the AlGaN layer 120 beneath the passivation layer 124.

Then, a recess 138 is etched in the exposed AlGaN layer 120 under low pressure conditions (for vertical etch, as shown in FIG. 2(d)), or a Fluorine-based plasma treatment 136 of the exposed AlGaN layer 120 under low pressure conditions (as shown in FIG. 2(e)), is used to deplete 134 the charge below the gate 108. Alternatively, both a recess 138 is etched in the exposed AlGaN layer 120, under low pressure conditions (for vertical etch), and a Fluorine-based plasma treatment 136 of the exposed AlGaN layer 120, under low pressure conditions, is used to deplete 134 the charge below the gate 108, as shown in FIG. 2(f).

Finally, as shown in FIGS. 2(g)-(i), wherein a gate 108 of a HEMT 100, 102 or 104 is fabricated, which includes integrating a slant field plate 106 with the gate 108 of the HEMT 100, 102 or 104, wherein the slant field plate is integrated with the gate 108 by shaping one or more sidewalls 112 of the gate 108, so that at least one portion 110 of the sidewalls 112 overhangs a channel 114 of the HEMT 100, 102 or 104 by extending at an acute angle 116 away from the channel 114. The gate 108 may be shaped using a variety of methods, including, but not limited to, using a mold layer (for example, a passivation layer 124) and depositing gate metal in the mold.

The gate metal 108 is deposited on the slanted features 128 and on the exposed AlGaN with an angled rotation to form the integrated field plate 106. For example, gate metal 108 may be deposited in the recess 138 as shown in FIG. 2(g), on the Fluorine-treated AlGaN 136 as shown in FIG. 2(h), or in the recess 138 and on the Fluorine-treated AlGaN 136 as shown in FIG. 2(i). The inherent field-plating splits the peak electric field into two separate peaks, and the slant 112 of the gate metal 108 and the rounded edges 118 cause the peak fields to spread further, resulting in high breakdown voltages.

Insertion of various insulating layers (any combination of silicon nitride, aluminum oxide, and any other insulating material with thicknesses ranging from 0.1 to 1000 Å) below the gate metal can further improve the performance of these devices by lowering gate leakage (which leads to higher breakdown voltage) and increasing the gate turn-on voltage (which leads to higher maximum currents and lower on-resistance). Since polarization fields in GaN and other related materials (AlN, GaN, InN, AlGaN, InGaN, AlInN, AlInGaN) can be used to create a conductive channel similar to AlGaN/GaN heterostuctures, the proposed technology can be applied there as well. Therefore, the present invention is not limited to AlGaN/GaN HEMTs where the first nitride material 120 is AlGaN and the second nitride material 122 is GaN. Other nitride materials can be used for the first nitride material (nitride barrier layer 120) and for the second nitride material 122 (buffer layer, for example).

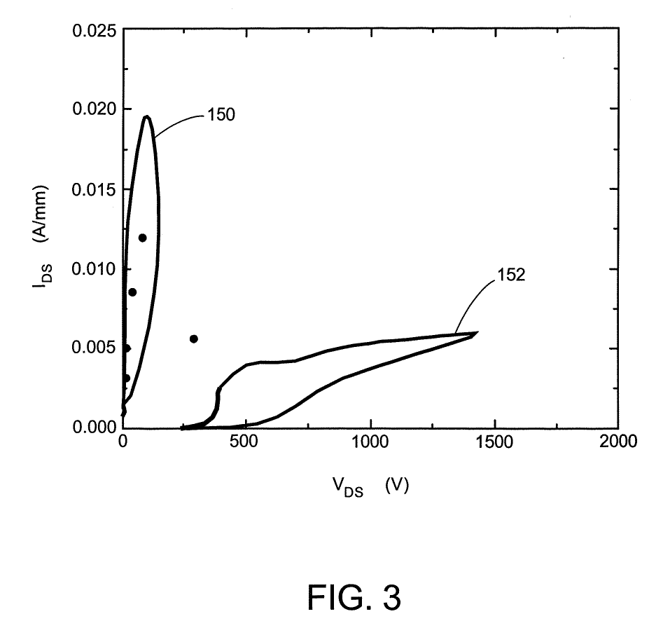

An off-state DC-IV plot of the first demonstration of E-mode AlGaN/GaN HEMT with integrated slant field plate is shown in FIG. 3. Previously, reported record breakdown voltage in a gate-recessed E-mode AlGaN/GaN HEMT with a source-terminated field plate was approximately 470 V and the on-resistance was approximately 0.0039Ω cm² represented by the V_{GS}=0 Vcurve 150 in FIG. 3, where V_{GS} is the gate-source voltage. Furthermore, these devices were limited by maximum current of 83 mA/mm. The destructive breakdown of our device exceeded 1400 V, and the on-resistance was approximately 0.0023Ω cm², as shown by the V_{GS}=2 V curve 152 in FIG. 3, which is beyond Si and SiC material limits. Thus, FIG. 3 shows how the HEMT of the present invention has increased breakdown voltage and reduced on-resistance as compared to a gate which does not have an integrated slant field plate.

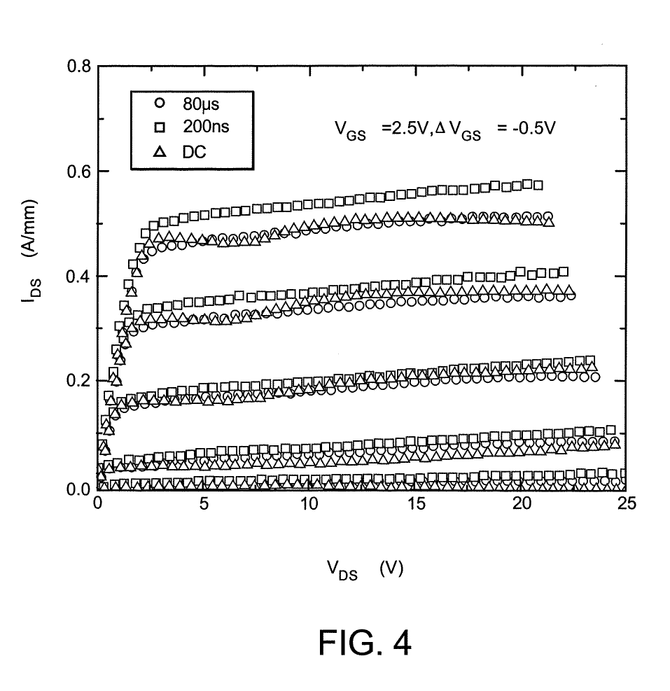

The DC, 80 μs, and 200 ns pulsed-IV plots shown in FIG. 4 indicate these devices are fully passivated. The maximum current exceeded 500 mA/mm. In FIG. 4, the DC, 80 μs, and 200 ns pulsed-IV data was measured for V_{GS}=2.5 V, V_{GS}=2.0 V, V_{GS}=1.5 V, V_{GS}=1.0 V, and V_{GS}=0.5 V, labeled 154, 156, 158, 160 and 162, respectively in FIG. 4 (i.e., V_{GS} was decreased in −0.5 V increments from V_{GS}=2.0 V).

### REFERENCES

The following references are incorporated by reference herein.
[1] Y. Dora, A. Chakraborty, L. McCarthy, S. Keller, S. P. DenBaars, and U. K. Mishra, “High breakdown voltage achieved on AlGaN/GaN HEMTs with integrated slant field plates,” submitted to IEEE Electron Device Letters (2006).
[2] W. B. Lanford, T. Tanaka, Y. Otoki, and I. Adesida, “Recessed-gate enhancement-mode GaN HEMT with high threshold voltage,” Electronics Letters, 41, pp. 449-450 (2005).
[3] Y. Cai, Y. Zhou, K. J. Chen, and K. M. Lau, “High-Performance Enhancement-Mode AlGaN/GaN HEMTs Using Fluoride-Based Plasma Treatment,” IEEE Electron Dev. Lett. 26, pp. 435-437 (2005).
[4] T. Palacios, C. S. Suh, A. Chakraborty, S. Keller, S. P. DenBaars, and U. K. Mishra, “High Performance Enhancement-Mode AlGaN/GaN HEMTs,” submitted to IEEE Electron Device Letters (2006).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An enhancement mode (E-mode) gallium nitride (GaN) based high electron mobility transistor (HEMT) having an integrated slant field plate that reduces a peak electric field under the HEMT's gate by spreading the electric field laterally from underneath the gate, wherein the integrated slant field plate is integrated with the gate by shaping the gate into a field plate.

2. The HEMT of claim 1, wherein at least one portion of at least one of the gate's sidewalls overhangs the HEMT's channel by extending or slanting at one or more acute angles away from the channel, thereby shaping the gate into a field plate.

3. The HEMT of claim 2, wherein the gate is a gate structure with an inherent field plate and rounded edges.

4. The HEMT of claim 3, wherein the integrated slant field plate splits peak electric fields under the gate into two smaller peaks, on either side of the gate and underneath the sidewalls, and the rounded edges broaden terminating points of electric fields in the HEMT, so that the HEMT exhibits higher breakdown voltages than conventional devices without the integrated slant field plate.

5. The HEMT of claim 4, wherein the HEMT's channel is a heterojunction formed between a first nitride material on a second nitride material and the gate contacts the first nitride material.

6. The HEMT of claim 5, wherein the first nitride material is AlGaN and the second nitride material is GaN.

7. The HEMT of claim 5, further comprising:
a passivation layer deposited on the first nitride layer;
an opening in the passivation layer having passivation layer sidewalls slanting at one or more acute angles away from the channel; and
gate metal deposited in the opening, on the passivation layer sidewalls, and on the first nitride material, to form the integrated slant field plate.

8. The HEMT of claim 7, wherein the passivation layer below the gate is etched using an etch condition that creates the slanted passivation layer sidewalls.

9. The HEMT of claim 5, wherein charge below the gate is removed by Fluorine-based plasma treatment of the first nitride material in a region where the gate contacts the first nitride material.

10. The HEMT of claim 5, wherein charge below the gate is removed by a recess etch of the first nitride material in a region where the gate contacts the first nitride material.

11. A gallium nitride (GaN) based high electron mobility transistor (HEMT) with an on resistance below 3 mΩ cm².

12. The HEMT of claim 11, with a gate breakdown voltage of at least 1400 V for a gate-source voltage of 0 V.

13. A method for fabricating a high electron mobility transistor (HEMT), comprising:
(a) depositing a passivation layer on a nitride barrier material of the HEMT;
(b) etching the passivation layer:
(1) to form one or more slanted features of the passivation layer extending at one or more acute angles away from the channel; and
(2) to expose some of the nitride barrier material beneath the passivation layer; and
(c) depositing gate metal on the exposed nitride barrier material and on the slanted features to form an integrated slant field plate.

14. A method for fabricating a gate of a high electron mobility transistor (HEMT), comprising integrating a slant field plate with a gate of the HEMT.

15. The method of claim 14, wherein the integrating comprises shaping one or more sidewalls of the gate so that at least one portion of the sidewalls overhangs a channel of the HEMT by extending at one or more acute angles away from the channel.

16. The method of claim 15, wherein the gate metal is deposited with an angled rotation to form a gate structure with an inherent field plate with rounded edges.

17. The method of claim 15, wherein the HEMT has increased breakdown voltage and reduced on-resistance as compared to a gate which does not have a slant field plate.
